(19) United States
(12) Patent Application Publication
(10) Pub. No.: US 2026/0005134 A1
(43) Pub. Date: Jan. 1, 2026

(54) INDUCTOR STRUCTURES IN HYBRID BONDED DEVICES

(71) Applicant: International Business Machines Corporation, Armonk, NY (US)

(72) Inventors: Kishan Jayanand, Cohoes, NY (US); Nicholas Alexander Polomoff, Hopewell Junction, NY (US); Viswas Purohit, East Amherst, NY (US); Nicholas Latham, Albany, NY (US); Ashim Dutta, Clifton Park, NY (US); Chih-Chao Yang, Glenmont, NY (US)

(21) Appl. No.: 18/760,156

(22) Filed: Jul. 1, 2024

(51) Int. Cl. H01L 23/522; H01L 23/00; H01L 23/48; H01L 23/528

(52) U.S. Cl. CPC H01L 23/5227; H01L 23/481; H01L 23/528; H01L 24/06; H01L 24/08; H10D 1/20; H01L 24/80; H01L 2224/0612; H01L 2224/08146; H01L 2224/80948

(57) ABSTRACT

A device comprises a first semiconductor structure disposed on a second semiconductor structure, and a plurality of metal structures at an interface portion of the first semiconductor structure and the second semiconductor structure. The first semiconductor structure comprises a first part of an inductor structure and the second semiconductor structure comprises a second part of the inductor structure. The plurality of metal structures connect the first part of the inductor structure with the second part of the inductor structure.

### BACKGROUND

Innovations in semiconductor fabrication and packaging technologies have enabled the development of smaller scale, higher density semiconductor integrated circuit (IC) chips, as well as the development of highly integrated chip modules with wiring and area array input/output (I/O) contact densities that enable dense packaging of IC chips. For certain applications, high-performance electronic devices are constructed by fabricating semiconductor devices on separate wafers and bonding the wafers together to construct an integrated semiconductor device package.

Various conventional techniques, such as two-dimensional (2-D) packaging and three-dimensional (3-D) packaging techniques, can be utilized to construct a semiconductor device package structure. With 2-D packaging, package structures can be constructed by connecting multiple semiconductor IC dies directly to a package substrate using direct chip attachment (DCA) techniques (e.g., flip-chip bonding), wherein the semiconductor IC chips are mounted in the package laterally adjacent to each other (e.g., in a single plane, or coplanar to each other). In this regard, 2-D packaging techniques can require a relatively large package footprint to accommodate multiple semiconductor IC chips. In addition, the I/O communication paths between adjacent chips can be very long since chip-to-chip I/O communication is made through chip-substrate-chip connections and interfaces, which can result in noisy and long interconnect lengths, which can degrade signal integrity.

On the other hand, with 3-D packaging, two more semiconductor IC chips are vertically stacked on top of each other, and interconnected. While 3-D packaging can provide improvement in communication bandwidth between the stacked chips, there are various problematic issues associated with 3-D packaging.

For example, some issues associated with current 3-D packaging approaches include, but are not limited to: (i) low capacitance structures; (ii) increased noise from power supplies at high frequency due to high speed circuit switching; (iii) decreased stack assembly yield, requiring more chip real estate for yield loss mitigation through, for example, redundancy; (iv) requirements for extra chip processing such as backside thinning to keep the stacked chips as thin as possible; (v) a chip stacking limits, etc.

### SUMMARY

Embodiments of the disclosure include hybrid bonding structures and techniques for hybrid bonding semiconductor structures with parts of an inductor structure to form an inductor.

In one embodiment, a device includes a first semiconductor structure disposed on a second semiconductor structure, and a plurality of metal structures at an interface portion of the first semiconductor structure and the second semiconductor structure. The first semiconductor structure comprises a first part of an inductor structure and the second semiconductor structure comprises a second part of the inductor structure. The plurality of metal structures connect the first part of the inductor structure with the second part of the inductor structure.

In another embodiment, a device includes a first semiconductor die disposed on a second semiconductor die. The first semiconductor die comprises a first part of an inductor structure and the second semiconductor die comprises a second part of the inductor structure. The first part of the inductor structure is connected with the second part of the inductor structure through an interface portion of the first semiconductor die and the second semiconductor die.

In another embodiment, an apparatus includes a first semiconductor die bonded to a second semiconductor die, an inductor structure comprising a first portion arranged within the first semiconductor die and a second portion arranged within the second semiconductor die, and a plurality of metal structures disposed along an interface between the first semiconductor die and the second semiconductor die. The first portion of the inductor structure, the plurality of metal structures, and the second portion of the inductor structure are in electrical contact with one another.

In another embodiment, an apparatus includes a first semiconductor structure disposed on top of and facing a second semiconductor structure. The apparatus further includes a plurality of metal structures spanning an interface portion between the first semiconductor structure and the second semiconductor structure. The plurality of metal structures connect a first part of an inductor on the first semiconductor structure to a second part of the inductor on the second semiconductor structure.

In another embodiment, a method includes forming a first semiconductor structure on a first semiconductor substrate, wherein the first semiconductor structure comprises a first part of an inductor structure, and a first plurality of metal pads connected to the first part of the inductor structure. The method further includes forming a second semiconductor structure on a second semiconductor substrate, wherein the second semiconductor structure comprises a second part of the inductor structure, and a second plurality of metal pads connected to the second part of the inductor structure. Respective ones of the first plurality of metal pads are aligned with respective ones of the second plurality of metal pads, and a hybrid bonding process is performed to bond the first semiconductor structure to the second semiconductor structure, wherein the hybrid bonding process integrates the first plurality of metal pads with the second plurality of metal pads to create a plurality of metal structures spanning an interface between the first semiconductor structure and the second semiconductor structure.

These and other features and advantages of embodiments described herein will become more apparent from the accompanying drawings and the following detailed description.

### BRIEF DESCRIPTION OF THE DRAWINGS

FIGS. 1 and 2 depict cross-sectional views of first and second semiconductor structures each including a portion of an inductor circuit, according to an embodiment of the invention.

FIGS. 3 and 4 depict cross-sectional views of first and second semiconductor structures following deposition of bonding level dielectric layers, according to an embodiment of the invention.

FIGS. 5 and 6 depict cross-sectional views of the first and second semiconductor structures following photoresist patterning and removal of portions of the bonding level dielectric layers to form openings for metal pads, according to an embodiment of the invention.

FIGS. 7 and 8 depict cross-sectional views of the first and second semiconductor structures following photoresist removal and seed/liner layer deposition, according to an embodiment of the invention.

FIGS. 9 and 10 depict cross-sectional views of the first and second semiconductor structures following deposition of metal fill layers, according to an embodiment of the invention.

FIGS. 11 and 12 depict cross-sectional views of the first and second semiconductor structures following planarization of the metal fill layers, according to an embodiment of the invention.

FIGS. 13 and 14 depict cross-sectional views of the first and second semiconductor structures following flipping of the first semiconductor structure onto the second semiconductor structure, and aligning of the first semiconductor structure with the second semiconductor structure, according to an embodiment of the invention.

FIG. 15 depicts a cross-sectional view of a hybrid bonding process of the first and second semiconductor structures, according to an embodiment of the invention.

FIG. 16 depicts a cross-sectional view of the first and second semiconductor structures following hybrid bonding, according to an embodiment of the invention.

FIG. 17 depicts a three-dimensional view of the hybrid bonded first and second semiconductor structures including through silicon vias (TSVs) on the first and second semiconductor structures, according to an embodiment of the invention.

FIGS. 18A, 18B and 18C depict respective first and second three-dimensional views and a top view of hybrid bonded inductor circuit portions in a first alternative configuration, according to an embodiment of the invention.

FIGS. 19A, 19B and 19C depict respective first and second three-dimensional views and a top view of hybrid bonded inductor circuit portions in a second alternative configuration, according to an embodiment of the invention.

FIGS. 20A, 20B and 20C depict respective first and second three-dimensional views and a top view of hybrid bonded inductor circuit portions in a third alternative configuration, according to an embodiment of the invention.

FIGS. 21A, 21B and 21C depict respective first and second three-dimensional views and a top view of hybrid bonded inductor circuit portions in a fourth alternative configuration, according to an embodiment of the invention.

FIGS. 22A, 22B and 22C depict respective first and second three-dimensional views and a top view of hybrid bonded inductor circuit portions in a fifth alternative configuration, according to an embodiment of the invention.

FIGS. 23A, 23B and 23C depict respective first and second three-dimensional views and a top view of hybrid bonded inductor circuit portions in a sixth alternative configuration, according to an embodiment of the invention.

### DETAILED DESCRIPTION

Embodiments of the disclosure will now be discussed in further detail with regard to structures and techniques for hybrid bonding semiconductor structures with parts of an inductor structure to form an inductor. It is to be understood that the various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration.” Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

Further, the term “semiconductor die” or “die” as used herein refers to a block of semiconductor material on which a given functional circuit (e.g., memory circuit, processor circuitry, etc.) and metallization levels (e.g., front-end-of-line (FEOL), middle-of-line (MOL), back-end-of-line (BEOL) metallization levels) are fabricated. Similarly, a semiconductor structure may also refer to a block of semiconductor material on which a given functional circuit and metallization levels are fabricated.

To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

As used herein, “high-K” refers to dielectric materials having a relative dielectric constant greater than 7.

As used herein, “low-K” refers to dielectric materials having a relative dielectric constant less than 7, and includes ultra-low-k dielectric materials.

As used herein, “hybrid bonding” refers to a 3D packing technique to connect semiconductor structures. Hybrid bonding forms connections of semiconductor structures through metal pads which are embedded in a dielectric layer at a bond interface on each semiconductor structure that is being bonded. Fusion bonding forms connections of semiconductor structures via dielectric layers at a bond interface on each semiconductor structure being bonded.

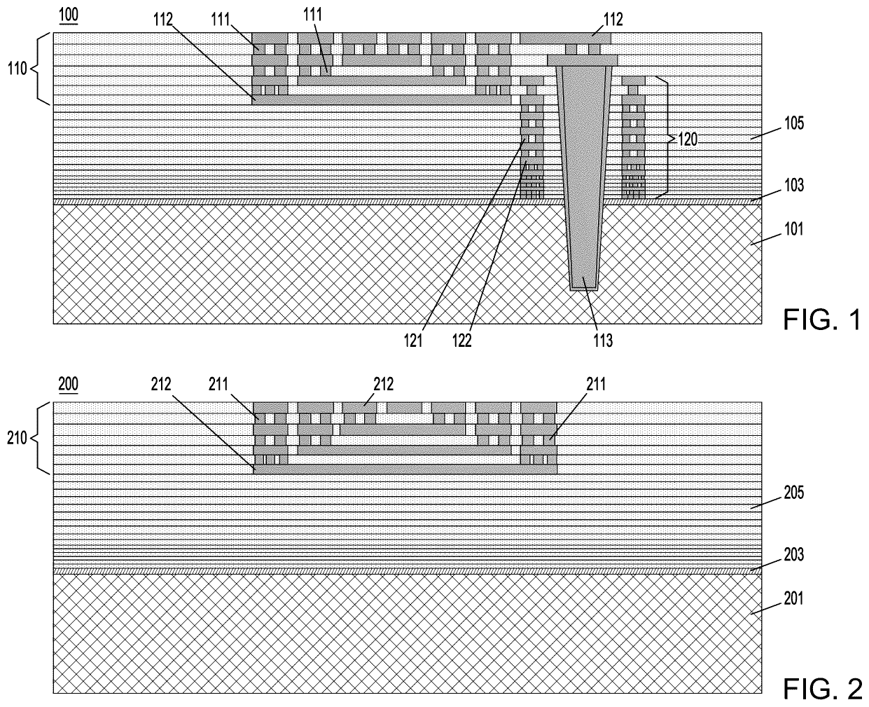

Referring to FIGS. 1 and 2, a first semiconductor structure 100 and a second semiconductor structure 200 (or “first semiconductor die” and “second semiconductor die”) are formed on a first semiconductor substrate 101 and a second semiconductor substrate 201, respectively. A first semiconductor substrate 101 and a second semiconductor substrate 201 include semiconductor materials including, but not limited to, silicon, III-V, II-V compound semiconductor materials or other like semiconductor materials. In addition, multiple layers of the semiconductor materials can be used as the semiconductor material of the first and second semiconductor substrates 101 and 201. Respective first and second base dielectric hermetic layers 103 and 203 are formed on the first and second semiconductor substrates 101 and 201. The first and second base dielectric hermetic layers 103 and 203 comprise, for example, silicon nitride (SiN) layers that are disposed on top of the first and second semiconductor substrates 101 and 201 before processing.

The first and second semiconductor structures 100 and 200 respectively include a first part 110 of an inductor circuit and a second part 210 of the inductor circuit. Inductor circuits may also be referred to herein as “inductor structures.” As can be seen, the first part 110 and the second part 210 of the inductor circuit each include a plurality of metallization levels (e.g., FEOL, MOL and BEOL metallization levels) in a first dielectric layer stack 105 and a second dielectric layer stack 205. The first semiconductor structure 100 further includes additional metallization structures 120 formed in the first dielectric layer stack 105.

The first and second dielectric layer stacks 105 and 205 include, but are not necessarily limited to, tetraethyl orthosilicate (TEOS), silicon dioxide (SiO₂), carbon-doped silicon oxide (SiCOH), SILK® dielectrics, and/or porous forms of these low-k dielectric films. The first and second dielectric layer stacks 105 and 205 include multiple layers of the same or different materials deposited in multiple deposition steps depending on the design and fabrication processes associated with the first and second semiconductor structures 100 and 200. As can be understood by one of ordinary skill in the art, the first and second dielectric layer stacks 105 and 205 can be on the first and second semiconductor substrates 101 and 201, with intervening layers (e.g., lower conductive lines, devices, etc.) between the first and second dielectric layer stacks 105 and 205 and the first and second semiconductor substrates 101 and 201. A plurality of devices can be on or within the first and second semiconductor substrates 101 and 201, such as, for example, transistors, capacitors, and resistors. For example, in illustrative embodiments, there are additional wiring levels and structures along with devices (e.g., transistors) within the first and second dielectric layer stacks 105 and 205 and connecting to devices that are built into the first and second semiconductor substrates 101 and 201 through the first and second base dielectric hermetic layers 103 and 203.

The first part 110 and the second part 210 of the inductor circuit each include a plurality of metallization levels respectively including a plurality of first metal layers 112 and a plurality of second metal layers 212 as shown by the horizontal lines. The first and second metal layers 112 and 212 can include, for example, wiring that is present on a chip.

The first metal layers 112 are connected to each other by one or more first vias 111 and the second metal layers are connected to each other by one or more second vias 211. The first and second vias 111 and 211 are illustrated as vertical lines between the horizontal lines representing the first and second metal layers 112 and 212. Similarly, the additional metallization structures 120 formed in the first dielectric layer stack 105 include a plurality of metallization levels comprising a plurality of additional metal layers 122 as shown by the horizontal lines, which can also include, for example, wiring that is present on a chip. The additional metal layers 122 are connected to each other by one or more additional vias 121 also illustrated as vertical lines between the horizontal lines representing the additional metal layers 122.

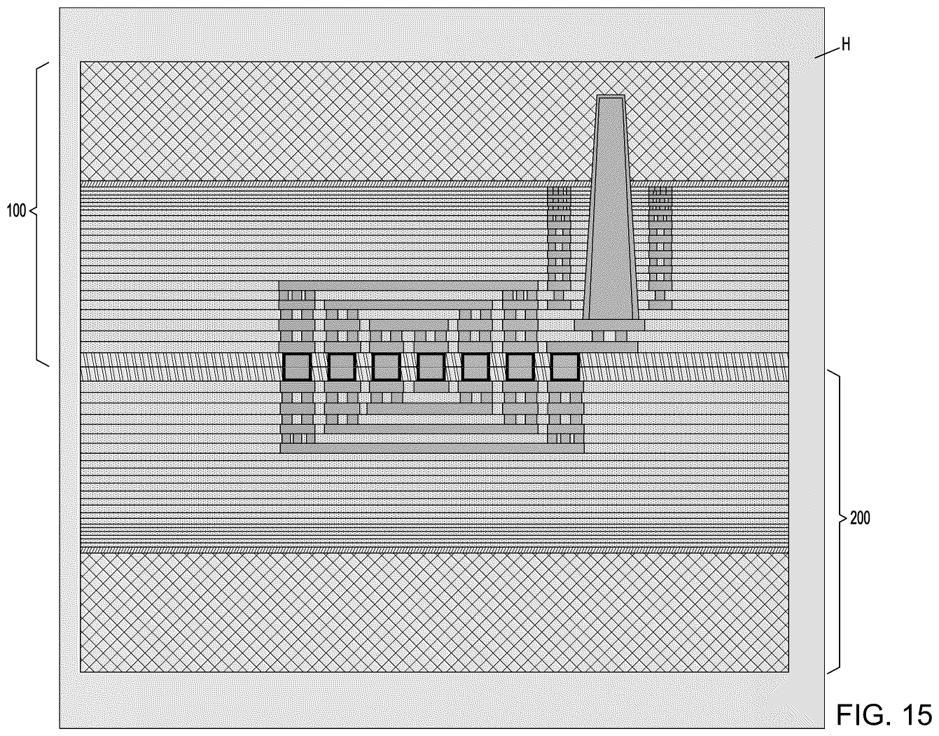

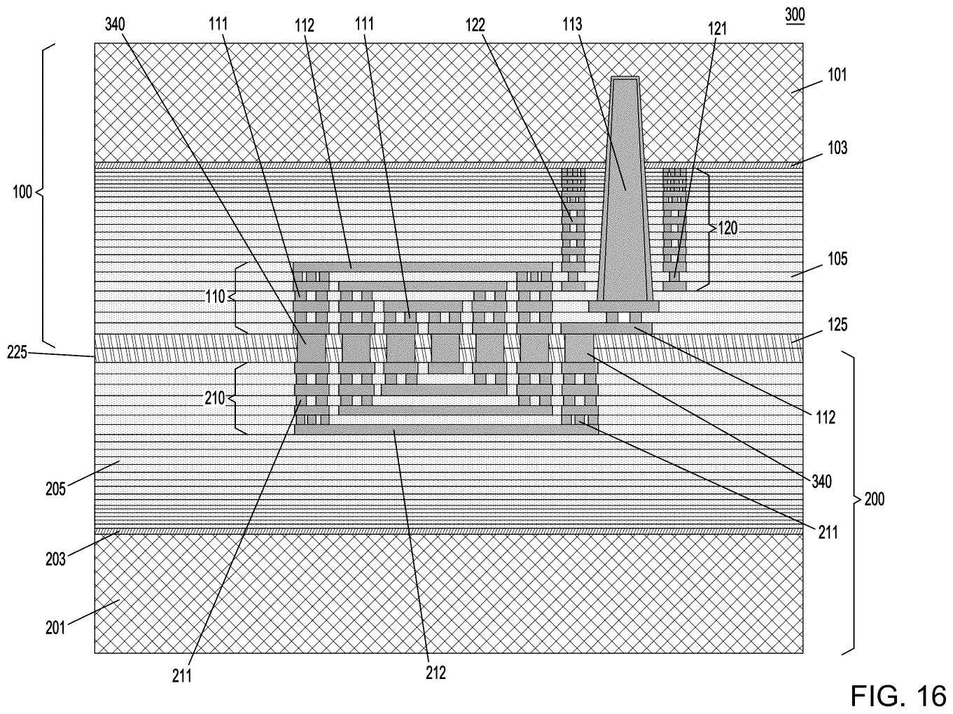

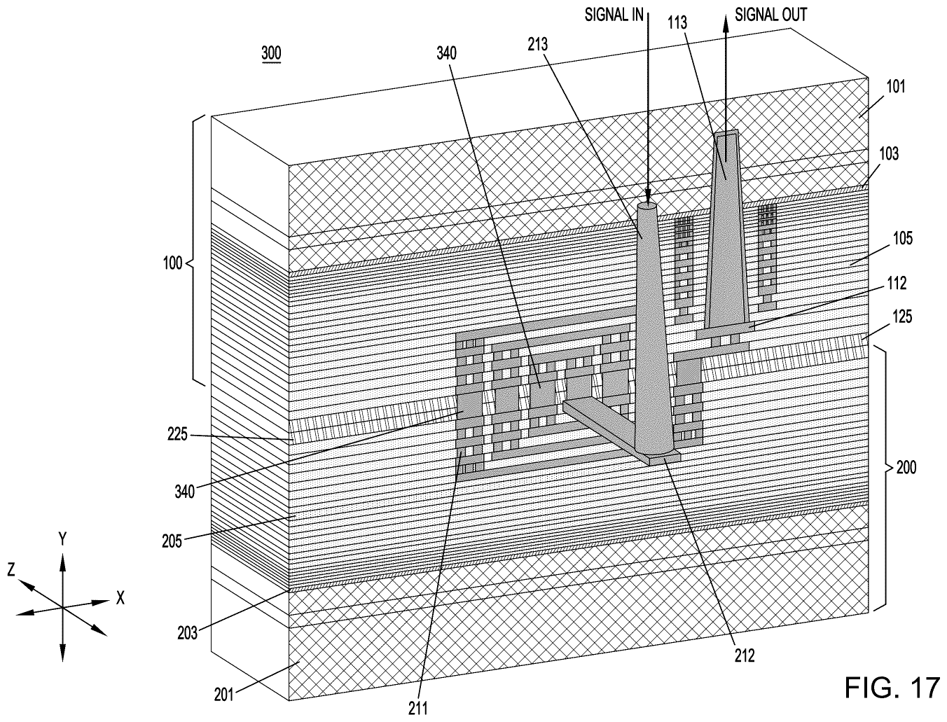

In addition, as explained in more detail herein, a first through silicon via (TSV) 113 extends from one of the first metal layers 112 of the first part 110 of the inductor circuit, through the first dielectric layer stack 105 and through the first base dielectric hermetic layer 103 into the first semiconductor substrate 101. As explained in more detail herein, the first TSV 113 can connect to one or more circuits (not shown) to deliver an output signal (e.g., voltage) from the inductor circuit. Similarly, as explained in more detail in connection with FIG. 17, a second TSV 213 extends from one of the second metal layers 212 of the second part 210 of the inductor circuit and connects to one or more circuits (not shown) to receive an input signal (e.g., voltage) for the inductor circuit.

In illustrative embodiments, the first and second vias 111 and 211, the first and second metal layers 112 and 212, the additional vias 121, the additional metal layers 122, and the first and second TSVs 113 and 213 include, for example, a silicide layer, such as a silicide formed with Ni, Ti, NiPt, etc., a metal adhesion layer, such as TiN, and a conductive metal fill layer, such as Cu, W, Al, Co, Ru, etc., and can be deposited using, for example, a deposition technique such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP) to remove excess portions of the metal material from on top of dielectric layers.

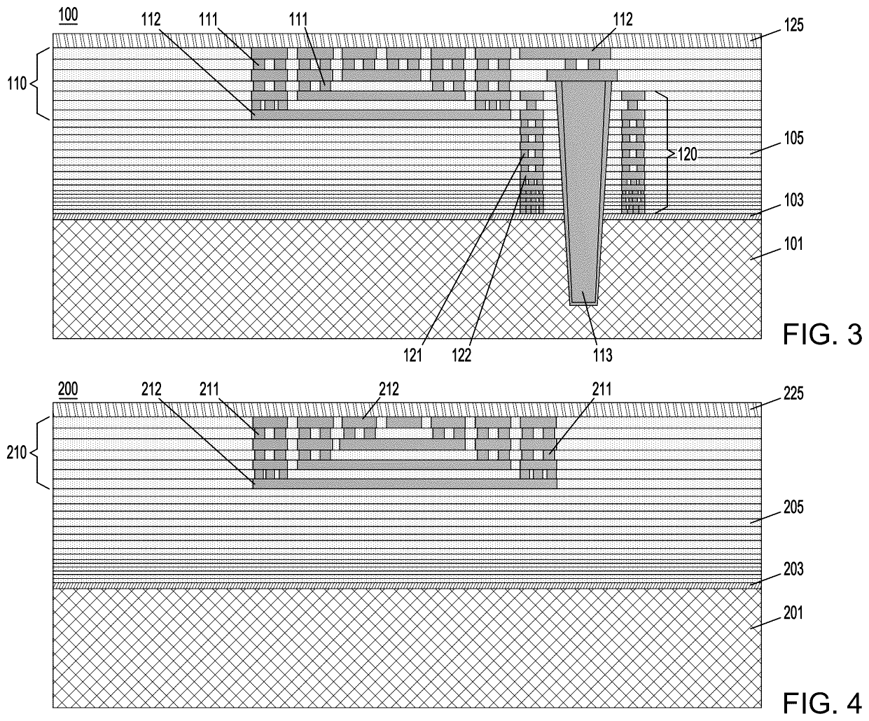

As shown in FIGS. 3 and 4, a first hybrid bonding level dielectric layer 125 is deposited on the top surface of the first dielectric layer stack 105. Similarly, a second hybrid bonding level dielectric layer 225 is deposited on the top surface of the second dielectric layer stack 205. The first and second hybrid bonding level dielectric layers 125 and 225 include, but are not necessarily limited to, TEOS, silicon-carbon-nitride (SiCN), silicon dioxide (SiO₂), silicon nitride (Si₃N₄), silicon oxynitride (SiON), and/or high-K dielectrics such as, but not necessarily limited to, HfO₂ (hafnium oxide), ZrO₂ (zirconium dioxide), and/or Ta₂O₅ (tantalum pentoxide) and/or other dielectric films. The first and second hybrid bonding level dielectric layers 125 and 225 can include the same dielectric material as each other or different dielectric materials from each other.

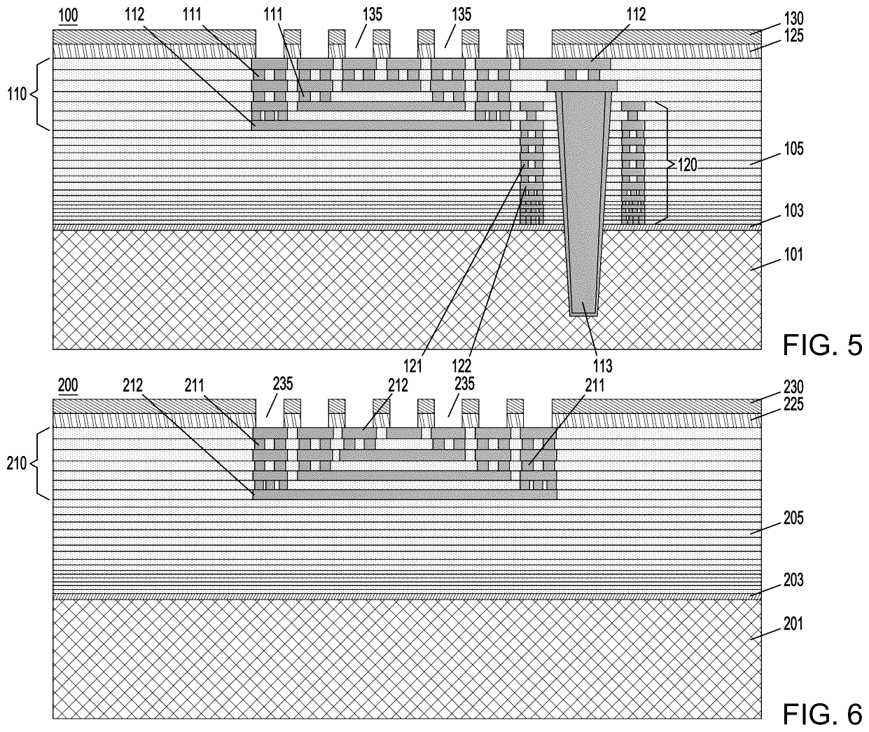

Referring to FIGS. 5 and 6, a first photoresist 130 and a second photoresist 230 are respectively deposited on first and second hybrid bonding level dielectric layers 125 and 225. The first and second photoresists 130 and 230 are patterned to create openings corresponding to where metal pads are to be formed. The openings in the first and second photoresists 130 and 230 expose portions of the first and second hybrid bonding level dielectric layers 125 and 225 that are etched to create first and second openings 135 and 235 exposing upper ones of the first metal layers 112 of the first part 110 of the inductor circuit and upper ones of the second metal layers 212 of the second part 210 of the inductor circuit. The etching can be performed using a reactive ion etching (RIE) process.

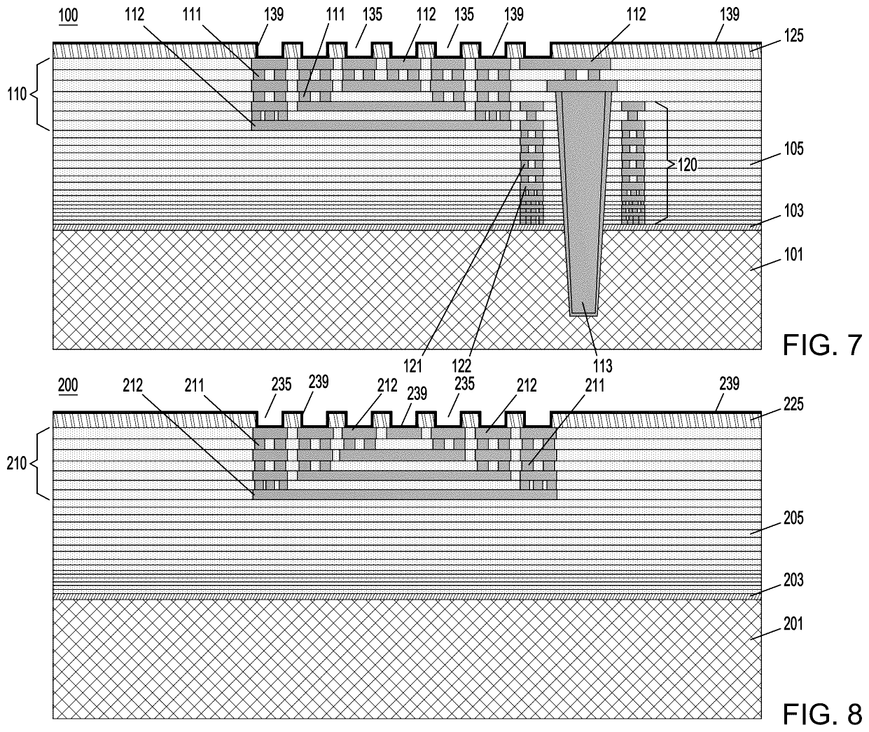

Referring to FIGS. 7 and 8, following etching of the exposed portions of the first and second hybrid bonding level dielectric layers 125 and 225 to create the first and second openings 135 and 235, the first and second photoresists 130 and 230 are removed. Following the removal of the first and second photoresists 130 and 230, a first seed/liner layer 139 is deposited on the remaining portions of the first hybrid bonding level dielectric layer 125 and the exposed portions of the first metal layers 112. Similarly, a second seed/liner layer 239 is deposited on the remaining portions of the second hybrid bonding level dielectric layer 225 and the exposed portions of the second metal layers 212. According to illustrative embodiments, the first and second seed/liner layers 139 and 239 each include, for example, Ti/TiW, Ti/TiN, Ta/TaN, TaN/Co, CuMn, Cu and other copper alloys.

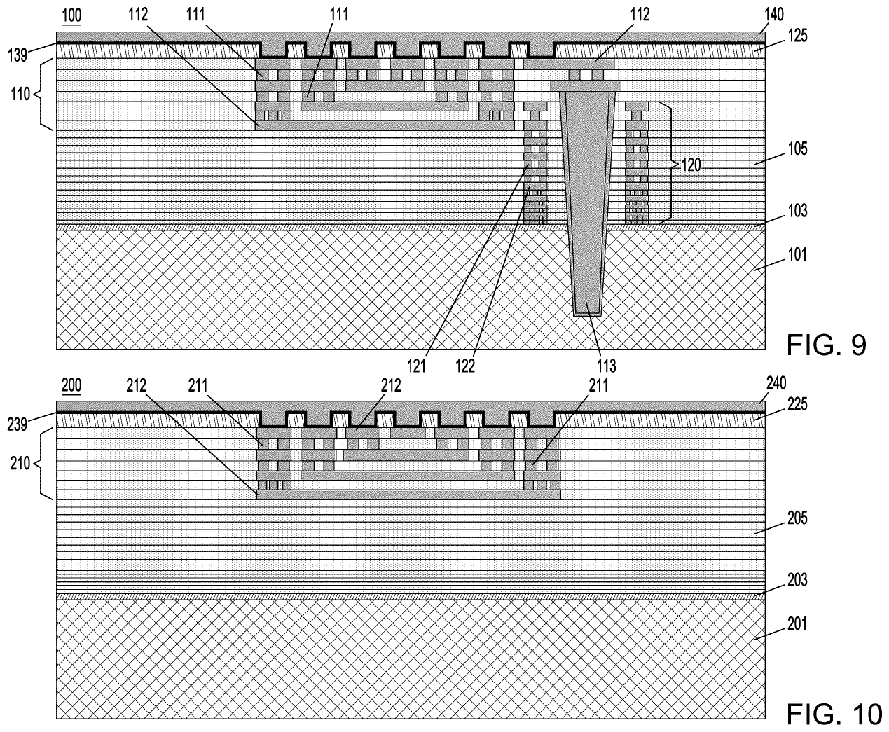

Referring to FIGS. 9 and 10, following deposition of the first and second seed/liner layers 139 and 239, a first metal fill layer 140 is formed on the first seed/liner layer 139 and a second metal fill layer 240 is formed on the second seed/liner layer 239. As can be seen in FIGS. 9 and 10, the first and second metal fill layers 140 and 240 fill-in the remaining portions of the first and second openings 135 and 235 in the first and second hybrid bonding level dielectric layers 125 and 225. In illustrative embodiments, the metal fill layers are formed in a plating process or other deposition process noted herein above for metal deposition, and include, for example, Cu, W, Al, Co, Ru, etc.

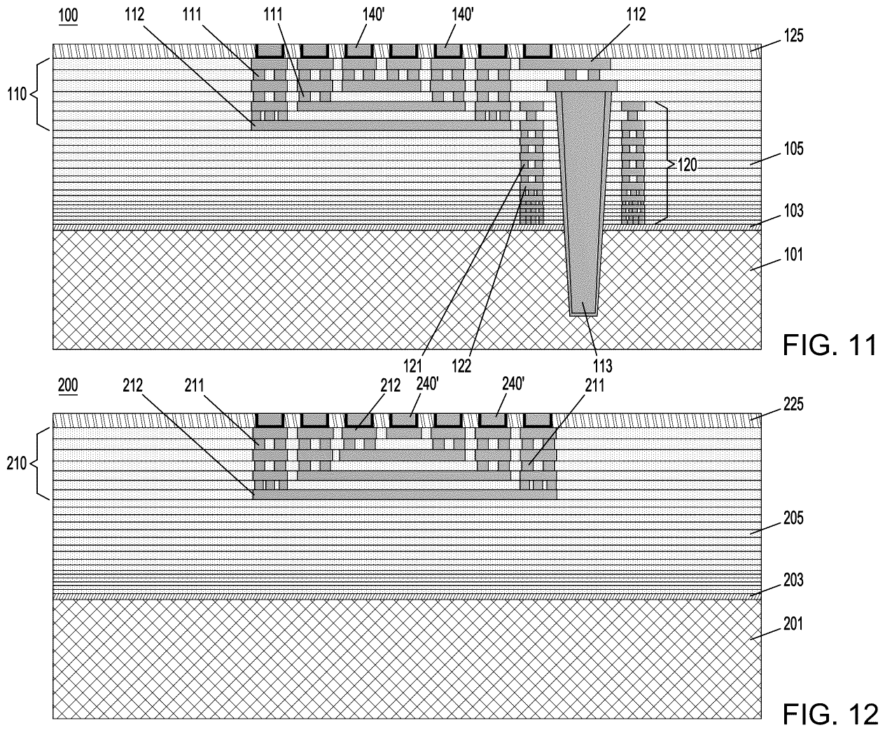

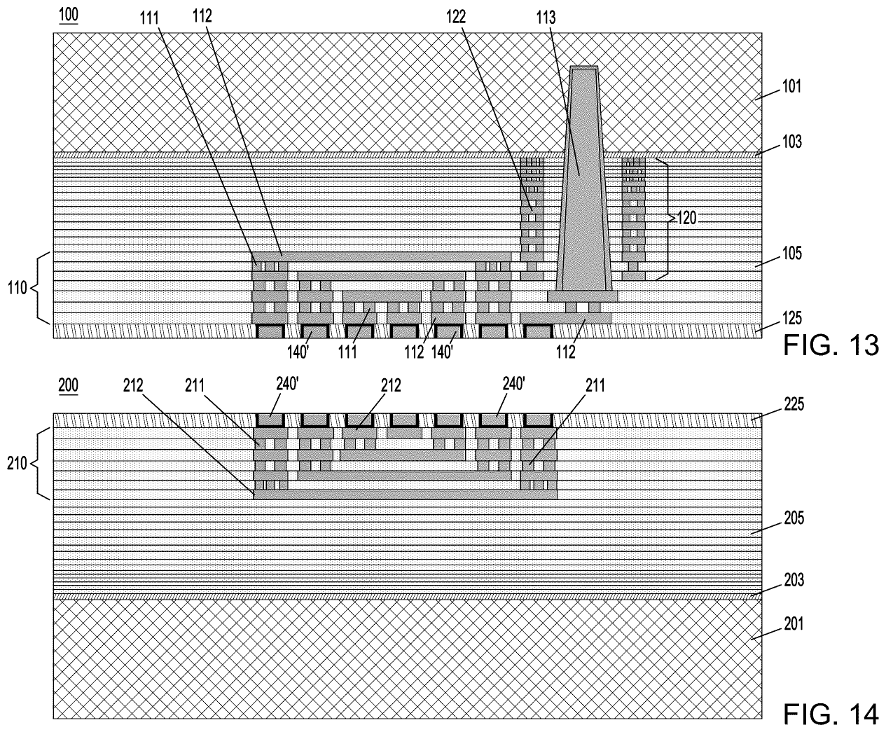

Referring to FIGS. 11 and 12, using, for example, CMP, the first and second metal fill layers 140 and 240, and the first and second seed/liner layers 139 and 239 are planarized from top surfaces of the first and second hybrid bonding level dielectric layers 125 and 225, resulting in first metal pads 140′ and second metal pads 240′ in the first and second openings 135 and 235, respectively. Then, referring to FIGS. 13 and 14, the first semiconductor structure 100 is flipped (e.g., rotated 180 degrees) onto the second semiconductor structure 200 so that the first semiconductor structure 100 faces the second semiconductor structure 200. As used herein, the terms “face,” “faces” or “facing” refer to the result of rotating one of two structures 180 degrees so that top surfaces of the structures can be positioned opposite and aligned with each other.

In flipping the first semiconductor structure 100 onto the second semiconductor structure 200, first metal pads 140′ of the first semiconductor structure 100 are aligned with second metal pads 240′ of the second semiconductor structure 200. The first metal pads 140′ are connected to first metal layers 112 on the first hybrid bonding level dielectric layer 125 in the orientation shown in FIG. 13. The second metal pads 240′ are connected to the second metal layers 212 under the second hybrid bonding level dielectric layer 225 in the orientation shown in FIG. 14. Respective first metal pads 140′ are disposed opposite to respective second metal pads 240′. The first metal pads 140′ are embedded in the first hybrid bonding level dielectric layer 125, and the second metal pads 240′ are embedded in the second hybrid bonding level dielectric layer 225. In illustrative embodiments, the first metal pads 140′ are recessed within the first hybrid bonding level dielectric layer 125 to allow for expansion of the first metal pads 140′ during annealing to form the hybrid bonds. Similarly, the second metal pads 240′ are recessed within the second hybrid bonding level dielectric layer 225 to allow for expansion of the second metal pads 240′ during annealing to form the hybrid bonds. In a non-limiting illustrative embodiment, the amount of recessing may be in the range of about 3 nm to about 5 nm.

Referring to FIG. 15, a hybrid bonding process H is performed on the first and second semiconductor structures 100 and 200 to anneal the metal material of the first metal pads 140′ and of the second metal pads 240′. Referring to semiconductor device 300 in FIG. 16, as a result of the annealing, the opposing first and second metal pads 140′ and 240′ are formed (e.g., integrated) into respective metal structures 340 that span (e.g., bridge) across an interface between the first and second semiconductor structures 100 and 200. The metal structures 340 are respectively connected to a first metal layer 112 of the first semiconductor structure 100 and a second metal layer 212 of the second semiconductor structure 200 on opposite sides of the metal structures 340. By virtue of the connections to the first and second metal layers 112 and 212, the metal structures 340 connect the first part 110 of the inductor circuit to the second part 210 of the inductor circuit to form the complete inductor circuit. The metal structures 340 are formed in the first and second hybrid bonding level dielectric layers 125 and 225. The first and second hybrid bonding level dielectric layers 125 and 225 may comprise the same dielectric material as each other or different dielectric materials from each other. The conditions of the hybrid bonding process include, for example, heat treating at about 200° C. to about 400° C. for about 1 hour to 3 hours. In an illustrative embodiment, the heat treatment is performed at 300° C. to about 400° C. for about 1 hour to about 2 hours. In illustrative embodiments, hybrid bonding uses thermal and mechanical forces to create the bonds.

As can be seen in the three-dimensional view of the semiconductor device 300 in FIG. 17, as explained in more detail herein, the first TSV 113 extends from one of the first metal layers 112 of the first part 110 of the inductor circuit, through the first dielectric layer stack 105 and through the first base dielectric hermetic layer 103 into the first semiconductor substrate 101. The first TSV 113 is connected to one or more circuits (not shown) to deliver an output signal (e.g., voltage) (Signal Out) from the inductor circuit. The second TSV 213 extends from one of the second metal layers 212 of the second part 210 of the inductor circuit and connects to one or more circuits (not shown) to receive an input signal (e.g., voltage) (Signal In) for the inductor circuit. The second TSV 213 extends through the first and second hybrid bonding level dielectric layers 125 and 225, through the first dielectric layer stack 105, through the first base dielectric hermetic layer 103 and into the first semiconductor substrate 101.

As can be seen in FIGS. 16 and 17, the first part 110 of the inductor circuit has a same configuration (e.g., coil) as the second part 210 of the inductor circuit. Alternatively, since the first and second semiconductor structures 100 and 200 can be manufactured separately and later hybrid bonded to each other, the first and second parts of the inductor circuit can have different configurations as long as they are connected to each other by the integrated metal structures formed as a result of heat treating the first and second metal pads of the opposing semiconductor structures during a hybrid bonding process. In illustrative embodiments, the coil or ring structure extends up and/or down through BEOL dielectric stacks (e.g., first and second dielectric layer stacks 105 and 205) to increase effective inductance.

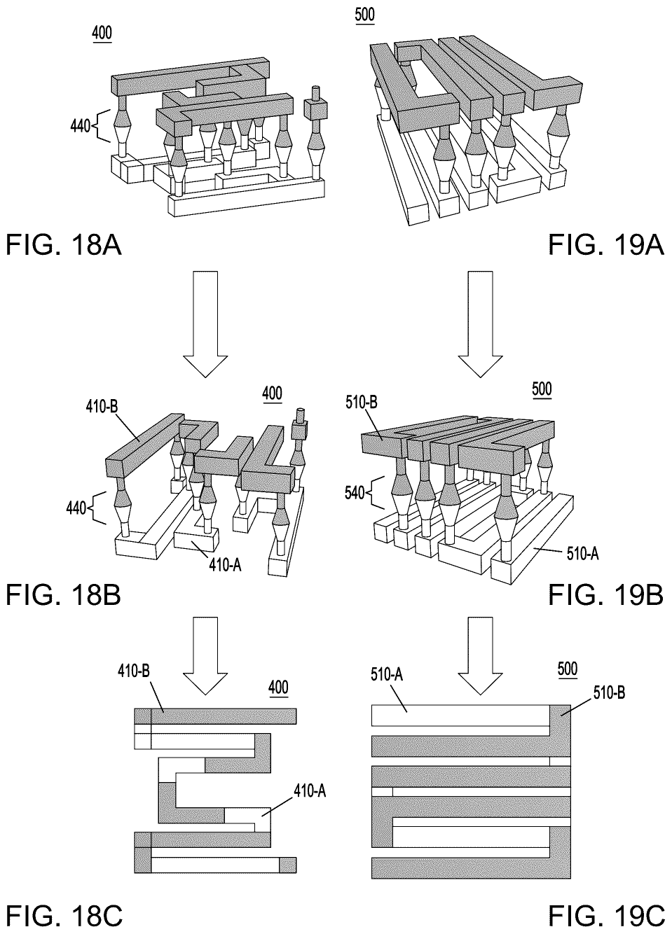

FIGS. 18A-23C illustrate different possible configurations of inductor circuit parts formed on opposing semiconductor dies. Referring to FIGS. 18A, 18B and 18C, which depict respective first and second three-dimensional views and a top view of a semiconductor device 400, first and second inductor circuit portions 410-A and 410-B are connected to each other by hybrid bonded metal structures 440. The first inductor circuit portion 410-A is formed on a first semiconductor die and the second inductor circuit portion 410-B is formed on a second semiconductor die that is hybrid bonded to first semiconductor die through the hybrid bonded metal structures 440.

Referring to FIGS. 19A, 19B and 19C, which depict respective first and second three-dimensional views and a top view of a semiconductor device 500, first and second inductor circuit portions 510-A and 510-B are connected to each other by hybrid bonded metal structures 540. The first inductor circuit portion 510-A is formed on a first semiconductor die and the second inductor circuit portion 510-B is formed on a second semiconductor die that is hybrid bonded to first semiconductor die through the hybrid bonded metal structures 540.

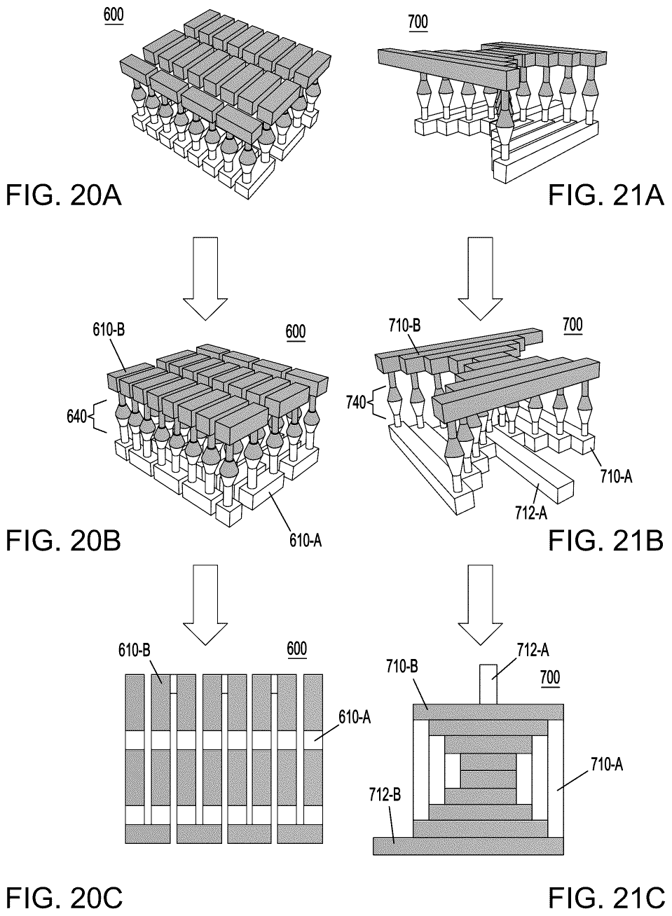

Referring to FIGS. 20A, 20B and 20C, which depict respective first and second three-dimensional views and a top view of a semiconductor device 600, first and second inductor circuit portions 610-A and 610-B are connected to each other by hybrid bonded metal structures 640. The first inductor circuit portion 610-A is formed on a first semiconductor die and the second inductor circuit portion 610-B is formed on a second semiconductor die that is hybrid bonded to first semiconductor die through the hybrid bonded metal structures 640.

Referring to FIGS. 21A, 21B and 21C, which depict respective first and second three-dimensional views and a top view of a semiconductor device 700, first and second inductor circuit portions 710-A and 710-B are connected to each other by hybrid bonded metal structures 740. The first inductor circuit portion 710-A is formed on a first semiconductor die and the second inductor circuit portion 710-B is formed on a second semiconductor die that is hybrid bonded to first semiconductor die through the hybrid bonded metal structures 740. First metal layer 712-A and second metal layer 712-B are representations of metal layers from which first and second TSVs would extend.

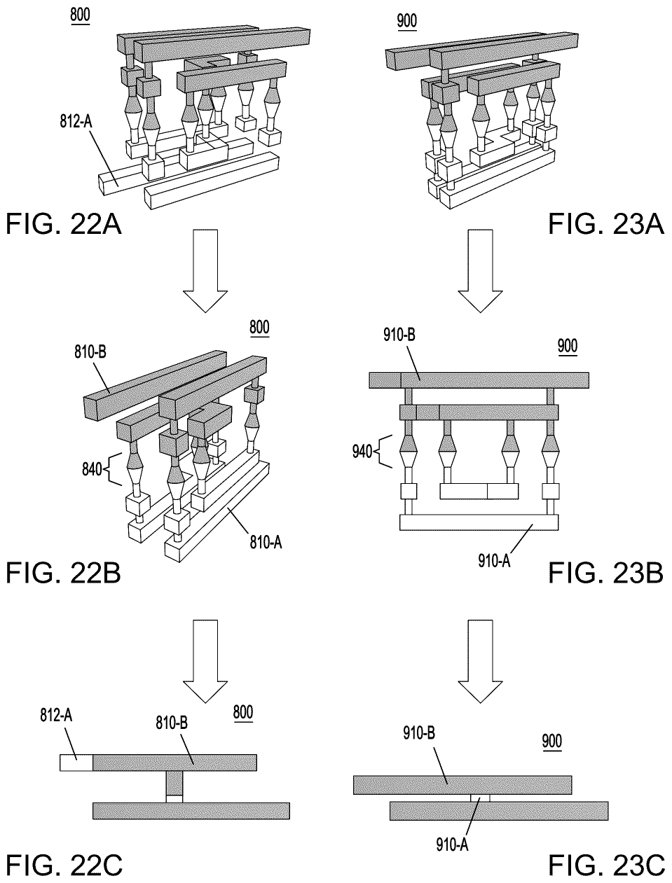

Referring to FIGS. 22A, 22B and 22C, which depict respective first and second three-dimensional views and a top view of a semiconductor device 800, first and second inductor circuit portions 810-A and 810-B are connected to each other by hybrid bonded metal structures 840. The first inductor circuit portion 810-A is formed on a first semiconductor die and the second inductor circuit portion 810-B is formed on a second semiconductor die that is hybrid bonded to first semiconductor die through the hybrid bonded metal structures 840. First metal layer 812-A is a representation of a metal layer from which a first TSV would extend.

Referring to FIGS. 23A, 23B and 23C, which depict respective first and second three-dimensional views and a top view of a semiconductor device 900, first and second inductor circuit portions 910-A and 910-B are connected to each other by hybrid bonded metal structures 940. The first inductor circuit portion 910-A is formed on a first semiconductor die and the second inductor circuit portion 910-B is formed on a second semiconductor die that is hybrid bonded to first semiconductor die through the hybrid bonded metal structures 940.

The hybrid bonded metal structures 440, 540, 640, 740, 840 and 940 are similar to the metal structures 340 described herein above to physically and electrically connect the parts of an inductor circuit to each other.

In one embodiment, a device includes a first semiconductor structure disposed on a second semiconductor structure, and a plurality of metal structures at an interface portion of the first semiconductor structure and the second semiconductor structure. The first semiconductor structure comprises a first part of an inductor structure and the second semiconductor structure comprises a second part of the inductor structure. The plurality of metal structures connect the first part of the inductor structure with the second part of the inductor structure.

The first part of the inductor structure may have a different configuration from or the same configuration as the second part of the inductor structure.

The first semiconductor structure may comprise at least a first conductive contact, wherein the device further comprises a first via connected to the first conductive contact. The first via may be connected to the second part of the inductor structure through one of the plurality of metal structures. The second semiconductor structure may comprise at least a second conductive contact, wherein the device further comprises a second via connected to the second conductive contact. The second via may be connected to the first part of the inductor structure through another one of the plurality of metal structures. The first via and the second via may respectively comprise a first TSV and a second TSV. One of the first via and the second via can receive an input voltage, and another one of the first via and the second via can output an output voltage.

The plurality of metal structures may be disposed in a dielectric layer, wherein the dielectric layer comprises at least two dielectric materials that are different from each other.

In another embodiment, a device includes a first semiconductor die disposed on a second semiconductor die. The first semiconductor die comprises a first part of an inductor structure and the second semiconductor die comprises a second part of the inductor structure. The first part of the inductor structure is connected with the second part of the inductor structure through an interface portion of the first semiconductor die and the second semiconductor die.

The device may further comprise a plurality of metal structures at the interface portion, wherein the plurality of metal structures connect the first part of the inductor structure with the second part of the inductor structure. The first semiconductor die may comprise at least a first conductive contact, wherein the device further comprises a first via connected to the first conductive contact. The first via may be connected to the second part of the inductor structure through one of the plurality of metal structures. The second semiconductor die may comprise at least a second conductive contact, wherein the device further comprises a second via connected to the second conductive contact. The second via may be connected to the first part of the inductor structure through another one of the plurality of metal structures. The first via and the second via may respectively comprise a first TSV and a second TSV. One of the first via and the second via can receive an input voltage, and another one of the first via and the second via can output an output voltage.

In another embodiment, In another embodiment, an apparatus includes a first semiconductor die bonded to a second semiconductor die, an inductor structure comprising a first portion arranged within the first semiconductor die and a second portion arranged within the second semiconductor die, and a plurality of metal structures disposed along an interface between the first semiconductor die and the second semiconductor die. The first portion of the inductor structure, the plurality of metal structures, and the second portion of the inductor structure are in electrical contact with one another.

The first portion of the inductor structure may have a different configuration from the second portion of the inductor structure. The first semiconductor die may comprise a first TSV connected to the second portion of the inductor structure through one of the plurality of metal structures. The second semiconductor die may comprise a second TSV connected to the first portion of the inductor structure through another one of the plurality of metal structures.

In another embodiment, an apparatus includes a first semiconductor structure disposed on top of and facing a second semiconductor structure. The apparatus further includes a plurality of metal structures spanning an interface portion between the first semiconductor structure and the second semiconductor structure. The plurality of metal structures connect a first part of an inductor on the first semiconductor structure to a second part of the inductor on the second semiconductor structure.

The first semiconductor structure may comprise a first TSV connected to the second part of the inductor through one of the plurality of metal structures. The second semiconductor structure may comprise a second TSV connected to the first part of the inductor through another one of the plurality of metal structures.

In another embodiment, a method includes forming a first semiconductor structure on a first semiconductor substrate, wherein the first semiconductor structure comprises a first part of an inductor structure, and a first plurality of metal pads connected to the first part of the inductor structure. The method further includes forming a second semiconductor structure on a second semiconductor substrate, wherein the second semiconductor structure comprises a second part of the inductor structure, and a second plurality of metal pads connected to the second part of the inductor structure. Respective ones of the first plurality of metal pads are aligned with respective ones of the second plurality of metal pads, and a hybrid bonding process is performed to bond the first semiconductor structure to the second semiconductor structure, wherein the hybrid bonding process integrates the first plurality of metal pads with the second plurality of metal pads to create a plurality of metal structures spanning an interface between the first semiconductor structure and the second semiconductor structure.

The method may further comprise forming a TSV on the first semiconductor structure, wherein the TSV is connected to the second part of the inductor structure through one of the plurality of metal structures. The hybrid bonding process comprises annealing the first plurality of metal pads and the second plurality of metal pads.

It is to be appreciated that the hybrid bonding techniques as disclosed herein enable construction of an inductor structure which provides various advantages over conventional 2-D and 3-D packaging structures and techniques as discussed above. For example, the structure advantageously provides techniques for fabricating a first inductor portion on a first semiconductor die, fabricating a second inductor portion on a second semiconductor die, and connecting the first and second semiconductor dies via a hybrid bond interface to form a multi-level inductor with an electrical connection between the inductor portions. The hybrid bond interface facilitates an electrical connection between the first and second inductor portions. As an additional advantage, the bifurcated structure of the inductor across two semiconductor dies allows for a modular design. This modularity allows for design flexibility, independent optimization of each semiconductor die, and easier integration with other components or systems.

Unlike conventional designs, the inductor structure includes several possible multi-level inductor structural configurations, with metal wires and bonding pads arranged in a pattern that creates a ring that extends up and/or down BEOL dielectric stacks to increase effective inductance, while providing a compact structure, thereby optimizing substrate area and allowing for advanced circuit designs and integration with other semiconductor devices.

Advantageously, the inductor structures of the illustrative embodiments can be used for radio frequency (RF) transmission and reception, and can be applied to RF and analog devices, which have become more prevalent with the growth of the wireless communication market. Additionally, the hybrid bonding methodology facilitates scalable and cost-efficient manufacturing processes, aligning production scalability with demand.

The innovative inductor design with a hybrid bond interface between two semiconductor dies results in enhanced electrical performance, compact integration, and scalable manufacturing. Inductance can be described in accordance with the following formula (1) using permeability of free space (μ₀), number of turns (N), area in an inner core (A), and length of a coil (l).

$$L = {μ}_{0} \frac{{N}^{2} A}{l} \qquad ( 1 )$$

The value of L can be changed with simple changes in the fabrication process.

As an additional advantage, the modular design of the illustrative embodiments caters to evolving wireless communication standards, aiding in the development of multi-band or reconfigurable communication systems. Application of the structures disclosed herein include, but are not necessarily limited to, cellular phones, wireless local area networks (LAN) and radio frequency identification (RFID), and radio frequency integrated circuits (RFICs).

Although exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A device, comprising:
a first semiconductor structure disposed on a second semiconductor structure;
wherein the first semiconductor structure comprises a first part of an inductor structure and the second semiconductor structure comprises a second part of the inductor structure; and
a plurality of metal structures at an interface portion of the first semiconductor structure and the second semiconductor structure;
wherein the plurality of metal structures connect the first part of the inductor structure with the second part of the inductor structure.

2. The device of claim 1, wherein the first part of the inductor structure has a different configuration from the second part of the inductor structure.

3. The device of claim 1, wherein the first part of the inductor structure has a same configuration as the second part of the inductor structure.

4. The device of claim 1, wherein:
the first semiconductor structure comprises at least a first conductive contact;
the device further comprises a first via connected to the first conductive contact; and
the first via is connected to the second part of the inductor structure through one of the plurality of metal structures.

5. The device of claim 4, wherein:
the second semiconductor structure comprises at least a second conductive contact;
the device further comprises a second via connected to the second conductive contact; and
the second via is connected to the first part of the inductor structure through another one of the plurality of metal structures.

6. The device of claim 5, wherein the first via and the second via respectively comprise a first through silicon via and a second through silicon via.

7. The device of claim 5, wherein:
one of the first via and the second via receives an input voltage; and
another one of the first via and the second via outputs an output voltage.

8. The device of claim 1, wherein the plurality of metal structures are disposed in a dielectric layer.

9. The device of claim 8, wherein the dielectric layer comprises at least two dielectric materials that are different from each other.

10. A device, comprising:
a first semiconductor die disposed on a second semiconductor die;
wherein the first semiconductor die comprises a first part of an inductor structure and the second semiconductor die comprises a second part of the inductor structure; and
wherein the first part of the inductor structure is connected with the second part of the inductor structure through an interface portion of the first semiconductor die and the second semiconductor die.

11. The device of claim 10, further comprising a plurality of metal structures at the interface portion, wherein the plurality of metal structures connect the first part of the inductor structure with the second part of the inductor structure.

12. The device of claim 11, wherein:
the first semiconductor die comprises at least a first conductive contact;
the device further comprises a first via connected to the first conductive contact; and
the first via is connected to the second part of the inductor structure through one of the plurality of metal structures.

13. The device of claim 12, wherein:
the second semiconductor die comprises at least a second conductive contact;
the device further comprises a second via connected to the second conductive contact; and
the second via is connected to the first part of the inductor structure through another one of the plurality of metal structures.

14. The device of claim 13, wherein the first via and the second via respectively comprise a first through silicon via and a second through silicon via.

15. The device of claim 13, wherein:
one of the first via and the second via receives an input voltage; and
another one of the first via and the second via outputs an output voltage.

16. An apparatus, comprising:
a first semiconductor die bonded to a second semiconductor die;
an inductor structure comprising a first portion arranged within the first semiconductor die and a second portion arranged within the second semiconductor die; and
a plurality of metal structures disposed along an interface between the first semiconductor die and the second semiconductor die, wherein the first portion of the inductor structure, the plurality of metal structures, and the second portion of the inductor structure are in electrical contact with one another.

17. The apparatus of claim 16, wherein the first portion of the inductor structure has a different configuration from the second portion of the inductor structure.

18. The apparatus of claim 16, wherein the first semiconductor die comprises a first through silicon via connected to the second portion of the inductor structure through one of the plurality of metal structures.

19. The apparatus of claim 18, wherein the second semiconductor die comprises a second through silicon via connected to the first portion of the inductor structure through another one of the plurality of metal structures.

20. An apparatus, comprising:
a first semiconductor structure disposed on top of and facing a second semiconductor structure; and
a plurality of metal structures spanning an interface portion between the first semiconductor structure and the second semiconductor structure;
wherein the plurality of metal structures connect a first part of an inductor on the first semiconductor structure to a second part of the inductor on the second semiconductor structure.

21. The apparatus of claim 20, wherein the first semiconductor structure comprises a first through silicon via connected to the second part of the inductor through one of the plurality of metal structures.

22. The apparatus of claim 21, wherein the second semiconductor structure comprises a second through silicon via connected to the first part of the inductor through another one of the plurality of metal structures.

23. A method, comprising:
forming a first semiconductor structure on a first semiconductor substrate, wherein the first semiconductor structure comprises a first part of an inductor structure, and a first plurality of metal pads connected to the first part of the inductor structure;
forming a second semiconductor structure on a second semiconductor substrate, wherein the second semiconductor structure comprises a second part of the inductor structure, and a second plurality of metal pads connected to the second part of the inductor structure;
aligning respective ones of the first plurality of metal pads with respective ones of the second plurality of metal pads; and
performing a hybrid bonding process to bond the first semiconductor structure to the second semiconductor structure, wherein the hybrid bonding process integrates the first plurality of metal pads with the second plurality of metal pads to create a plurality of metal structures spanning an interface between the first semiconductor structure and the second semiconductor structure.

24. The method of claim 23, further comprising forming a through silicon via on the first semiconductor structure, wherein the through silicon via is connected to the second part of the inductor structure through one of the plurality of metal structures.

25. The method of claim 23, wherein the hybrid bonding process comprises annealing the first plurality of metal pads and the second plurality of metal pads.
